(19) United States
(12) Patent Application Publication
(10) Pub. No.: US 2010/0084697 A1
(43) Pub. Date: Apr. 8, 2010

(54) NOVEL CAPACITORS AND CAPACITOR-LIKE DEVICES

(76) Inventors: Thilo KOPP, Stadtbergen (DE); Jochen Dieter MANNHART, Konigsbrunn (DE)

Correspondence Address: MARK D. SARALINO (GENERAL);RENNER, OTTO, BOISSELLE & SKLAR, LLP, 1621 EUCLID AVENUE, NINETEENTH FLOOR, CLEVELAND, OH, 44115-2191, US

(21) Appl. No.: 12/570,090

(22) Filed: Sep. 30, 2009

Related U.S. Application Data
(60) Provisional application No. 61/102,174, filed on Oct. 2, 2008.
(60) Provisional application No. 61/152,389, filed on Feb. 13, 2009.

(51) Int. Cl. H01L 29/92; H01G 4/00; H01G 4/008

(52) U.S. Cl. 257/296; 257/532; 361/301.1; 361/305; 257/E29.342

(57) ABSTRACT

A capacitor and capacitor-like device or any other device showing capacitive effects, including FETs, transmission lines, piezoelectric and ferroelectric devices, etc., with at least two electrodes, of which at least one electrode consists of or comprises a material or is generated as electron system, whose absolute value of the electronic charging energy as defined by the charging-induced change of Eₖᵢₙ+E_{exc}+E_{corr} exceeds 10% of the charging-induced change of the Coulomb field energy of the capacitor according to E=E_{coul}+Eₖᵢₙ+E_{exc}+E_{corr}. Therein, E is the energy of a capacitor and E_{coul}=Q²/2 C_{coul}=Q²d/(2 ε₀ εₓ A), A is the area of the capacitor electrodes, d is the distance and ε₀εₓ the dielectric constant between them. E_{corr} describes the correlation energy, Eₖᵢₙ the electronic kinetic energy and E_{exc} the exchange energy of the electrode material. Particularly in miniaturized devices, E_{coul} is becoming so small that, by using certain materials or material combinations for the capacitor, Eₖᵢₙ, E_{exc}, and/or E_{corr} provide significant contributions to E. Preferred are materials with strongly correlated electron systems such as perovskites like La₁₋ₓSrₓTiO₃, YBa₂Cu₃O_{7-d}, vanadates such as (V₁₋ₓAₓ)₂O₃ with A=Cr, Ti, materials with free electron gases of typically low densities such as Cs, Bi or Rb, or of materials the carrier density of which is reduced by diluting these materials in other materials with smaller carrier densities, metals like Fe, or Ni, materials with van-Hove singularities in the electronic density of states such as graphite or Bechgaard salts or even or 2D-electron gases generated by graphene or by heterostructures, such as the electron gases generated at LaAlO₃/SrTiO₃ or ZnO/(MgₓZn₁₋ₓ)O multilayers and more.

### CROSS-REFERENCE TO RELATED APPLICATION

This application claims priority under 35 U.S.C. §119 to U.S. Provisional Application Nos. 61/102,174, filed Oct. 2, 2008 and 61/152,389 filed on Feb. 13, 2009, the entire disclosure of which is incorporated herein by reference.

### TECHNICAL FIELD AND BACKGROUND OF THE INVENTION

The present invention relates to capacitors and capacitor-like devices, in principle to any device showing capacitive effects, particularly in miniaturized devices like integrated circuits. Today, practically all electronic devices use or are affected—often undesired—by the induction of charges due to electric fields. Examples are
Field effect transistors, such as MOSFETs, in which charging of the gate capacitors is used to turn the conductivity of drain-source channels on and off;
Transmission lines used to transmit voltage pulses in integrated circuits. The transmission speed of such transmission lines is limited by the time needed to charge the capacitor formed by the transmission line, the surrounding dielectric material, and other conducting circuit components that act as counter-electrodes;
Piezoelectric and ferroelectric devices.

As taught by classical electrostatics, the capacity of a capacitor is determined by its geometry and the dielectric constants εᵣ of the dielectric used. In a very simple, yet common case, two parallel conducting plates of area A are separated by a dielectric with thickness d. As is known [J. D. Jackson, Classical Electrodynamics, J. Wiley and Sons, 1998], the capacity C of such a capacitor equals

C=ε₀ εᵣ A/d (1),

where ε₀ is the dielectric constant of the vacuum.

Driven by the continuing miniaturization of electronic devices, capacitors and or capacitor-like devices with very high or very low capacities need to be fabricated. Usually, the geometrical configuration of the devices is subject to engineering boundary conditions, so that the only parameter remaining for the optimization of the capacity is εᵣ.

In MOSFETs, for example, large capacities are needed. The industry has therefore switched from using SiO₂ as gate dielectric to high-κ oxides such as Hf-based oxides (κ=εᵣ−1). Yet, such changes are costly, and future changes to even higher κ materials will be even more so.

Very small capacities are needed for transmission lines. They are therefore embedded in especially designed low-κ materials.

Here it has to be noted that these efforts are constrained by the range of available εᵣ values, which is limited by the availability of respective dielectrics.

Interestingly, Eq. 1 does not necessarily apply for the case that one electrode of the capacitor is provided by a two-dimensional, free electron gas generated in heterostructures fabricated from semiconductors such as Si, Ge, GaAs or (AlₓGa₁₋ₓ)As [S. Luryi, Appl. Phys. Lett. 52, 501 (1988), J. P. Eisenstein et al., Phys. Rev. Lett. 68, 674 (1992)]. The reason is the following: the energy required to charge such a capacitor is given by

E=E_{coul}+Eₖᵢₙ+E_{exc}.

Here, E_{coul} is the Coulomb energy of the charged particles of the electrodes, Eₖᵢₙ is the kinetic energy of the electrons, and E_{exc} is their quantum mechanical exchange energy.

As a result, the total capacity of such an arrangement is given by

1/C=1/C_{coul}+1/Cₖᵢₙ+1/C_{exc},

where C_{coul} is the standard capacity of the capacitor corresponding to Eq. 1.

Unfortunately, such two-dimensional electron gases in semiconductors can usually not be used to solve the problems described above, because the electronic properties and the heterostructures they require do in most cases not allow to integrate such electron gases as electrode materials into most integrated circuits in order to resolve these problems.

### SUMMARY OF THE INVENTION

In general, the energy of a capacitor is given by

E=E_{coul}+Eₖᵢₙ+E_{exc}30 E_{corr}, (2)

where E_{corr} describes the correlation energy of the electrode material [T. Kopp and J. Mannhart, Journal of Applied Physics 106, 064504 (2009)]. In result, the capacity of the capacitor is given by

1/C=1/C_{coul}+1/Cₖᵢₙ+1/C_{exc}+1/C_{corr}, (3)

where C_{corr} is the capacity that results from E_{corr}.

In most capacitor configurations used today, E_{coul} far exceeds Eₖᵢₙ, E_{exc}, and E_{corr}. Thus C˜C_{coul}, and Eq. 1 is therefore valid.

However, in miniaturized devices E_{coul} is becoming so small that practical and useful materials or material combinations exist for which Eₖᵢₙ, E_{exc}, or E_{corr} may provide significant contributions to E. Because 1/C_{exc} or 1/C_{corr} can acquire negative values, for given d and εᵣ capacitors may have smaller or larger capacities than described by Eq. 1.

In the following, a material of which the energies Eₖᵢₙ, E_{exc}, or E_{corr} are non-negligible as compared to E_{coul} for a given device configuration will be called a “material according to the invention” or short “MAI”.

MAIs include, for example, materials with strongly correlated electron systems such as
perovskites like La₁₋ₓSrₓTiO₃, YBa₂Cu₃O₇₋ₓ,
vanadates such as (V₁₋ₓAₓ)₂O₃ with A=Cr, Ti,
materials with free electron gases of typically low densities such as Cs, Bi or Rb, or of materials the carrier density of which is reduced by diluting these materials in other materials with smaller carrier densities,
metals like Fe, or Ni,
materials with van-Hove singularities in the electronic density of states such as graphite or Bechgaard salts or even
2D-electron gases generated by graphene or by heterostructures, such as the electron gases generated at LaAlO₃/SrTiO₃ or ZnO/(MgₓZn₁₋ₓ)O multilayers.

Electron systems with strong correlations are electron systems in which the Hubbard energy U of electrons or holes, i.e., the on-site Coulomb repulsion energy of two electrons or holes, is larger than the kinetic energy of the electrons.

Further MAIs are organic compounds or very thin layers of metals, possibly even monoatomic layers grown as epitaxial strained sheets. Here, the epitaxial strain or stress is applied to alter the carrier density of the metal to adjust the values of Eₖᵢₙ, E_{exc}, or E_{corr} for producing an optimized capacity.

By inserting MAIs into practical devices, the capacities of the devices are enhanced or decreased as compared to the value given by Eq. 1 and novel architectures for capacitors and capacitor-like devices can be realized. Doing so, the capacity of MOSFETs or transmission lines can for example be optimized in previously unknown ways.

It is noted that the desired modification of the capacities does not require a complete replacement of the material used for one or several of the capacitor electrodes with an MAI. Because, according to the laws of electrostatics, the net charges of a charged body collect on the outer surface of this body, it is sufficient to coat the active interface of such an electrode with a layer of an MAI or to introduce a thin layer by other means.

To summarize, the invention concerns a capacitor or a capacitor-like device with at least two electrodes, of which at least one electrode consists of or comprises a material or is generated or is generated as electron system, the absolute value of the electronic charging energy of which exceeds 10% of the Coulomb field energy of the capacitor.

### BRIEF DESCRIPTION OF THE DRAWINGS

FIG. 1 illustrates a capacitor according to the invention, the capacity of which is altered by an MAI layer.

FIG. 2 shows a field effect transistor according to the invention, the gate capacitor of which is altered by a layer of an MAI.

FIG. 3 illustrates a ferroelectric memory device according to the invention with an MAI between one of the electrodes and the ferroelectric material.

FIG. 4 depicts a piezoelectric actuator according to the invention with an MAI between one of the electrodes and the piezoelectric material.

FIG. 5 illustrates how different MAIs influence the charge density and the electric field distribution in an electronic device.

FIG. 6 depicts a cross-section through a detailed embodiment of a device according to the invention.

FIG. 7 shows a diagram of the properties of the device shown in FIG. 6.

FIG. 8 illustrates a memory device according to the invention.

FIG. 9 shows a cross-sectional sketch of a transmission line according to the invention.

FIG. 10 depicts a cross-sectional sketch of a large capacitor according to the invention. A capacitor with capacitance is formed a dielectric layer of HfO₂ separating a one atomic layer thick Rb film from a Si electrode (6).

### DETAILED DESCRIPTION

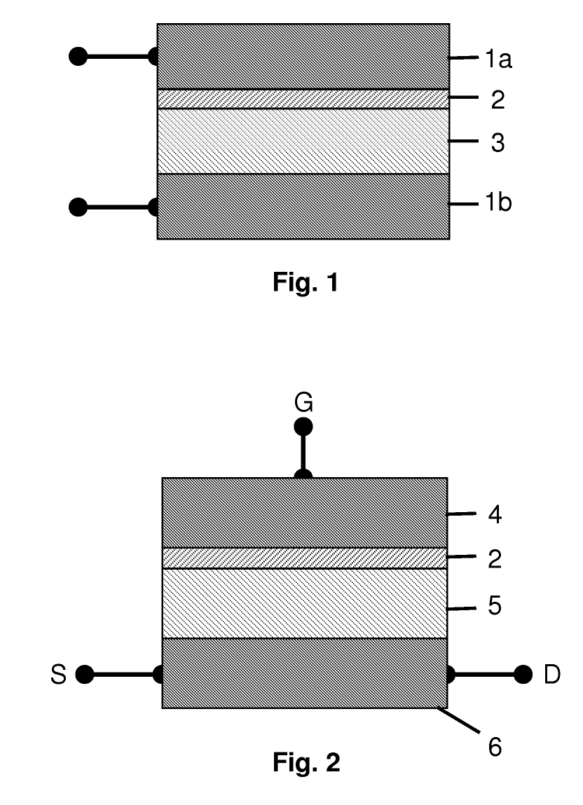

FIG. 1 illustrates a capacitor according to the invention with electrodes 1a and 1b separated by a standard dielectric 3. The capacity of this capacitor is altered by an MAI layer 2.

A capacitor according to the invention is shown in FIG. 1. Therein, the electrostatic property—and thus the capacitance—is determined by the MAI 2 and the dielectric 3. In such a configuration, even a 2D-electron gas of a semiconducting heterostructure may be integrated into a practical capacitor.

Preferable dimensions are:
a dielectric 3 having a thickness of less than (20 nm×εᵣ), εᵣ being the dielectric constant of the dielectric material used; and
an MAI of less than 50 nm thickness.

Thus, if air is the dielectric, the resulting thickness of the dielectric should be less than 20 nm. If a dielectric material with a high dielectric constant, e.g. larger than 10, is used, the dielectric may have a preferable thickness of less than 200 nm. Altogether, the thickness of the dielectric is not critical; it might be just one atomic layer, and in some cases it may also well exceed the preferable thickness.

Also, the thickness of the MAI does not seem to be critical either. Usually it would be thicker than the dielectric and be covered be a well-conducting electrode. However, depending on the MAI material used, the MAI may just form the electrode, i.e. would not be covered by a “separate” electrode.

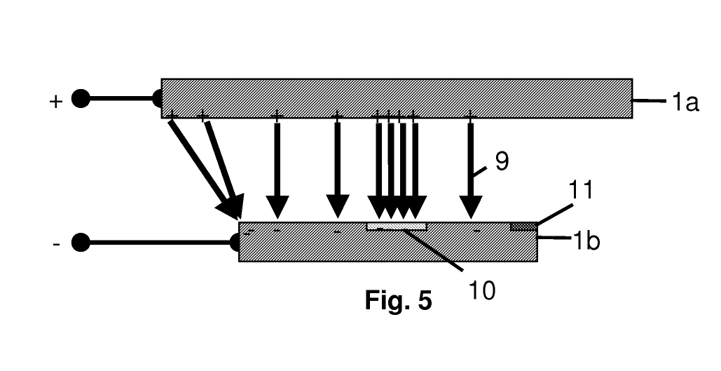

Moreover, if capacitors are fabricated in which one or several of the electrodes need only a small energy E upon charging, see section 10 of FIG. 5 as example, capacitors with large capacities are obtained. Such capacitors are in particular of interest to store large electric charges.

It must be understood that the capacity of a capacitor including an MAI also depends on the geometry and configuration of the capacitor, however in a way that differs from the capacities of the well-known, standard capacitors. This is because each MAI layer or MAI electrode adds an inverse capacitance 1/Cₖᵢₙ, 1/C_{exc}, and/or 1/C_{corr}, (see Eq. 2) apart from the C_{coul}. C_{coul} is caused by the electrical field distribution and thus by the geometrical arrangement of the set of electrodes. However, Cₖᵢₙ, C_{exc}, and C_{corr} are mostly determined by the material properties and geometry of the individual electrodes. Therefore, these capacities are not determined by the arrangement of electrode set in the manner well known from standard capacitors. Therefore, using MAIs to build capacitors allows novel designs for capacitors. The resulting freedom in layout is particularly useful for the design of electronic devices such as integrated circuits.

Likewise, if a “capacitive device” like a transmission line or its ground plane, is partially or fully coated with a thin layer of an MAI to yield a total capacity C<C_{coul}, a concomitant enhancement of speed, caused by a reduction of RC-times, LC-times, or switching times, is achieved.

Furthermore, new electrical components can be devised. If the arrangement is chosen such that one or more of the electrodes have a negative charging energy E that dominates the total energy of the capacitor, the total charging energy E of the capacitor is negative, i.e. a capacitor with a negative capacitance is obtained. Such a capacitor charges itself to a voltage that depends on the electrode materials, including the MAI, and the capacitor configuration. Due to their unique properties, such capacitors are useful in electronic circuits, for example to generate voltages and to lower or remove damping of devices. This may be beneficial in oscillatory circuits and other ones.

To exemplify, we consider a two-plate capacitor with identical plates. Such a capacitor with, for example, εᵣ=20, d=1.2 nm has a classical (inverse) capacitance according to Eq. (1):

4πε₀A/C_{coul}=4π/εᵣ=0.75 nm,

which is the effective distance between the two parallel plates. As this distance is nanoscopically small, the additional inverse capacitances in Eq. (3) are not negligible. The additional inverse quantum capacitances may be found from the determination of the electronic compressibility K through

A(1/Cₖᵢₙ+1/C_{exc}+1/C_{corr})=1/(e² n² K)

This relation is valid for each single plate. As written, it applies for plates with two-dimensional electron gases. For three-dimensional electron gases, the equation is slightly altered. If we take Cu, Au or Ag electrodes, the additional inverse capacity is positive and small, so that 4πε₀ A/C stays at approximately 0.75 (+0.15) nm for the addressed capacitor. However, if the electrodes are coated with an MAI, the capacity may be altered significantly. For example, with an Rb coating, we have 4πε₀/(e² n² K)=0.02 nm for an areal density of Rb atoms of 4.9×10¹⁴/cm², but 4πε₀/(e² n² K)=−0.42 nm for an areal density of 1.15×10¹⁴/cm² (G. D. Mahan, Many-Particle Physics, Plenum Press, 1990; B. Tanatar and D. M. Ceperley, Phys. Rev. B 39, 5005 (1989)). Accordingly, we find 4πε₀A/C=0.33 nm for the two-plate capacitor. This signifies an increase of the capacitance by far more than 100%.

In general, a coating with a material of which the inverse electronic compressibility satisfies

K⁻¹>( 1/10)e² n² d/(ε₀ εᵣ)

represents a coating with an MAI.

Another implementation of the invention are field effect devices in which conducting channels, such as drain source channels, consist of MAIs or are coated by such materials.

FIG. 2 shows a field effect transistor, here a MOSFET, according to the invention with a gate electrode 4, a conventional gate dielectric 5, and a drain-source channel 6. The gate capacitor of this MOSFET is altered by a layer of an MAI 2. This MAI results in a capacity C>C_{coul} of the MOSFET. The gate stack thus consists of the conductive gate electrode 4, the conductive MAI 2, and the gate dielectric 5 on the drain-source channel 6. The gate of such a MOSFET will have an enhanced, i.e. increased capacitance for given values of d and κ, as compared to a standard capacitor with the same values of d and κ. Such a MOSFET may be, e.g., operated with a reduced gate voltage.

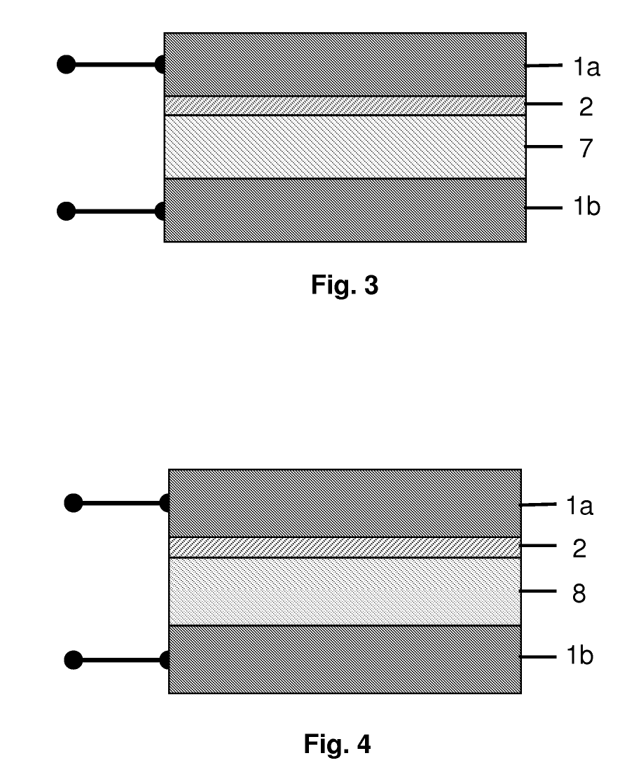

FIG. 3 illustrates a ferroelectric memory device according to the invention with electrodes 1a and 1b of a memory cell separated by a standard ferroelectric material 7, e.g. lead titanate (PbTiO₃), lead zirconate titanate (PZT) or lead lanthanum zirconate titanate (PLZT). An MAI 2 is located between one of the electrodes and the ferroelectric material. In such devices, information is stored as polarization of a ferroelectric medium. Now, as described above, by using an MAI with the total charging energy of the device can be enhanced or lowered, depending on the sign of Eₖᵢₙ+E_{exc}+E_{corr} of the MAI 2. Therefore, the write and readout voltage and/or speed of such a device can be optimized by selecting a material with the sum Eₖᵢₙ+E_{exc}+E_{corr} optimized for the specific device. For example, if the total energy is lowered, writing of information into such a device requires less energy and can therefore be done at increased speed. For other applications, the amount of stored energy needs to be maximized, which is done by enhancing the total energy with a MAI. The thickness of the ferroelectric material 7 depends on the requirement that the ferroelectric memory device has to fulfill; usually it would be comparable to a dielectric of a capacitor as shown in FIG. 1. In principle, the thickness of the ferroelectric material does not appear to be critical with regard to the functionality of the invention.

FIG. 4 illustrates how the invention can be applied to piezoelectric devices in which mechanical motion is coupled to electric fields. The conductive electrodes 1a and 1b of a piezoelectric actuator are separated by a standard piezoelectric material 8. The MAI 2 is positioned between one of the electrodes and this piezoelectric material. Now, embedding an MAI with energies E smaller or larger than E_{coul} into one or both of the electrodes, i.e. by choosing materials with a desirable total energy E, the input and output voltages of such piezoelectric devices can be optimized.

The thickness of the piezoelectric material 8 depends on the mechanical requirement; usually it would be thicker than a dielectric of a capacitor as shown in FIG. 1. Again, the thickness of the piezoelectric material does not appear to be critical with regard to the functionality of the invention.

FIG. 5 shows yet another an exemplary device which shall be used to explain the principle of the invention. Two conventional metallic plates, i.e. electrodes 1a and 1b, are charged by a voltage, indicated by the + and − signs. The lower electrode comprises two embedded MAI sheets or sections 10 and 11. The MAI of section 10 is characterized by a small charging energy E and thus attracts charges and electric field lines, indicated by arrows 9. The MAI of section 11 is characterized by a large charging energy E and thus attracts less charges and electric field lines than material 1b.

It is important to understand that in many materials Eₖᵢₙ, E_{exc}, and E_{corr} depend on external parameters such as magnetic or electric fields H, pressure P, epitaxial strain S, current density J flowing through the material, or temperature T. Therefore, by tuning H, P, S, J, and T, the respective component, e.g. a capacitor, may be tuned to optimize performance.

Likewise, by altering H, P, S, J, and T, a desired function may be obtained. In the case of a capacitor, because its capacitance depends on these parameters, such a device may be used as tunable capacitor or as sensor for H, P, J, and/or T. In memory devices, for example, bits stored as magnetization may be read out by the voltage of a capacitor according to the invention which is penetrated by the magnetic field H of the bits.

Another application are rf-filters which may include or consist of capacitors according to the invention which are tunable by H, P, S, J, and/or T.

Therefore, since by varying H, P, S, J, and T, an MAI usually changes its physical properties, multiferroism is achievable. The resulting resistance changes are useful for applications in many electronic devices such as switches and amplifiers. Here it is in particular mentioned that electrical conductivities may be varied.

It should be understood that in all devices described above, more than one layer containing an MAI may be used. In cases where the device contains more than one electrode, e.g. the configurations of FIG. 1 and FIG. 3, such MAI layers may be embedded in a symmetric fashion, i.e. with the same thickness, distribution and/or material on both electrodes. However, there may be applications where asymmetric arrangements are preferable, i.e. only one MAI layer or multiple MAI layers of different thicknesses and/or materials are used.

Another implementation of the invention are capacitors in which, for example by electronic reconstruction, at least one layer of a MAI is generated at the contact between two different materials or at a surface of a material.

A further implication of the invention is that by substituting part of an electrode by an MAI or by embedding an MAI into an electrode, the charge distribution of such an electrode is modified and differs from the charge distribution generated by standard electrode materials of the same configuration. Consequently, in the presence of an electric field, the distribution of the field lines is accordingly altered. FIG. 5 shows the principle. Thus, electric field lines and therefore also electric currents can, e.g. be focused onto desired areas, for example to extract charges. Or, where desirable, areas can be shielded from electric fields and currents. This may be important to prevent electric breakthrough phenomena. Thus, including MAI structures or compositions into electrodes or other device components allows to generate desirable distributions of charge densities, electric fields and currents without altering the overall geometrical configuration of an electrode or a device.

Likewise, if materials are used in electronic devices for engineering reasons different than optimizing C, their properties resulting from their electronic energy E may also have unwanted effects. For example, non-linear capacities may cause non-linearities in the device properties. Such detrimental effects can be minimized by optimizing E according to the invention, i.e. by selecting an optimized design of one or more MAI layers or sections.

Based on the above description and the given examples and applications, a person skilled in the art can easily vary the described invention, its values, and its materials given above, and adapt the invention to other implementations without departing from the inventive gist.

### SOME EXAMPLES OF EMBODIMENTS

Plate capacitors with capacitances that exceed the value given by Eq. 1 are, for example, readily fabricated in the following ways. It is understood that these embodiments present examples of a much larger variety of possible ways available to fabricate such devices.

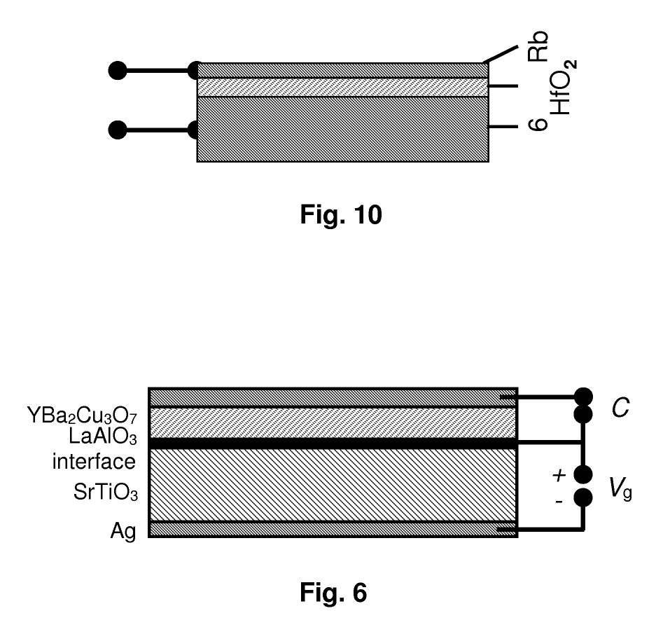

FIG. 6 shows a first embodiment in detail, a capacitor. It consists of a YBa₂Cu₃O₇—LaAlO₃—SrTiO₃—Ag heterostructure in which the YBa₂Cu₃O₇forms a circular electrode with a diameter of 0.35 mm and the LaAlO₃ layer is 3.8 nm thick. At large gate voltages (V_{G}>0.4), the carrier density of the LaAlO₃—SrTiO₃ interface is so large that C-enhancement effects are negligible. The capacitance (˜3900 pF) corresponds to the geometrical capacitance as expected from Eq. 1 for a capacitor with εᵣ˜18. At smaller gate voltages (e.g. V_{G}˜0.3 V), the capacitance is much enhanced as compared to the value expected from Eq. 1. These yet unpublished data were measured at 4.2 K by Prof. R. Ashoori and his group at MIT on samples fabricated in the laboratories of the inventors.

Therein, the lower of the two electrodes is provided by the conducting interface of a LaAlO₃—SrTiO₃ bilayer. This electrode is readily formed by using a [100] SrTiO₃ single crystal substrate that is etched according to the procedures provided in a paper by Kawasaki, M., Takahashi, K., Maeda, T., Tsuchiya, R., Shinohara, M., Ishiyama, O., Yonezawa, T., Yoshimoto, M. & Koinuma H.: “Atomic control of the SrTiO₃ crystal surface”, Science 266, 1540-1542 (1994) to be terminated by a TiO₂ atomic plane. On this substrate, a 1.6 nm thick interface layer of LaAlO₃ is grown, for example by pulsed laser deposition, using a LaAlO₃ crystal as target, a substrate temperature of 800 C, an oxygen background pressure of 8×10⁻⁵ mbar, and a film thickness control by reflective high energy electron diffraction (RHEED). After growth, the sample may be cooled to room temperature in an oxygen atmosphere of 0.5 bar. Alternatively, the conducting interface can be obtained by growing the LaAlO₃ layer by molecular beam epitaxy (MBE).

The carrier density of this interface layer is a function of the deposition parameters, in particular of the oxidizing conditions. For the samples grown by MBE, carrier densities of ˜5×10¹²/cm² are obtained; for layers grown by laser ablation carrier densities of ˜4×10 cm¹³/cm² are generated. When the films are grown at a reduced oxygen pressure, higher carrier densities are present. It is noted that for experimental studies the carrier concentration may also be controlled by applying a gate voltage between the interface electron system and an additional electrode deposited on the back side of the SrTiO₃ substrate.

The upper of the two electrodes is, for example, provided by an epitaxial film of YBa₂Cu₃O₇ with a thickness of 10 nm. This layer may also be grown by pulsed laser deposition. Likewise, a metal electrode, such as a Au film grown by sputtering to a thickness of 10 nm may be used.

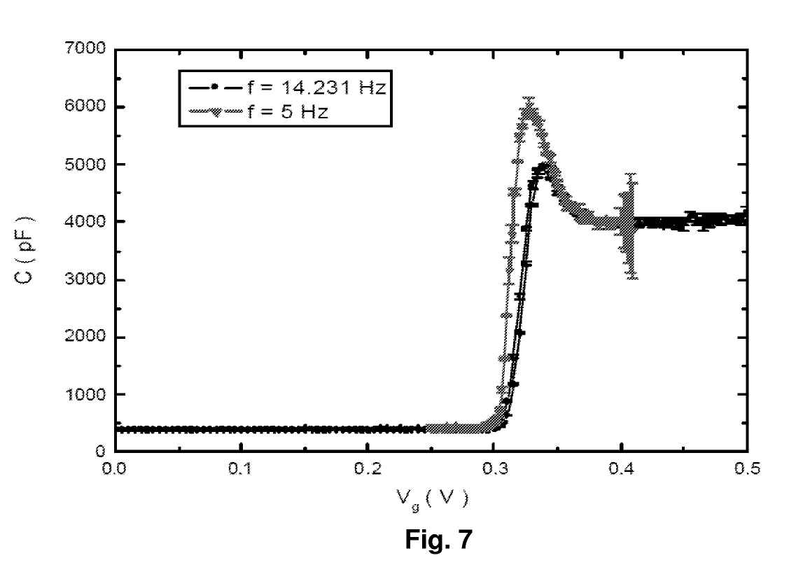

FIG. 7 is a diagram of the properties of the capacitor shown in FIG. 6. As can be seen, a capacity may be obtained that exceeds the capacitance as described by Eq. 1 by more than 50%.

In this case, by adjusting the growth conditions, a capacitor has been fabricated in which the carrier density is so small that a conducting interface serving as capacitor electrode is only present if a positive electric voltage Vg is applied between the back of the SrTiO₃ and the LaAlO₃—SrTiO₃ interface so that the carrier density of the interface is enhanced. For Vg>0.4V, the carrier density of the LaAlO₃—SrTiO₃ interface is so large that the capacitor formed by the SrTiO₃—LaAlO₃—YBa₂Cu₃O₇ structure has a capacity according to the textbook equation Eq. 1. For a smaller carrier density present at the interface, induced by smaller Vg, the measured capacitance increases well above the value given by Eq. 1. In this case, the capacitance corresponds to that of a capacitor that has a dielectric with a dielectric constant exceeding that of LaAlO₃ films by a factor 1.5.

FIG. 8 shows a memory device in form of an FET or capacitor-like device according to the invention which comprises a layer of a MAI 2. The memory device has a gate electrode 4 and a drain-source channel (DS channel) 6. Such a device is characterized by two minima of its E(Q)-characteristic, i.e. there are two stable states corresponding to these two minima and presenting the stored information. The electric field lines generated by the gate electrode G and that act on the DS channel differ between these two states. Because the electric field lines change the conductivity of the DS channel, the information can be easily read out by measuring the resistance of the DS channel. After writing the information into these devices, no gate voltage is needed, therefore non-volatile memory cells are obtained which are highly miniaturizable.

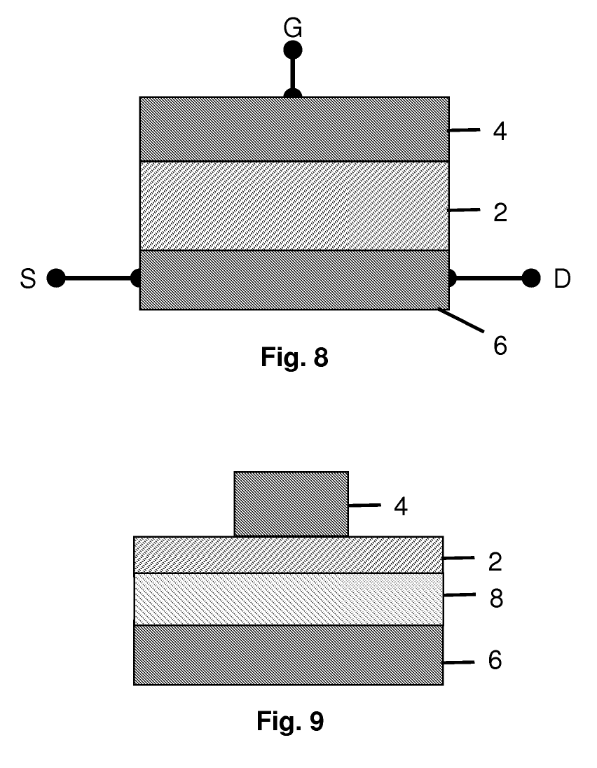

FIG. 9 depicts a cross-sectional sketch of a transmission line forming or comprising a capacitor or capacitor-like device according to the invention. The transmission line is formed by the signal line 4, the MAI 2 as coating on the signal line, a conventional dielectric material 8, and a ground-plane 6. Here, the capacitance of the capacitor having the signal line and the ground plane as electrodes is kept below the geometric capacitance of a capacitor given by these two electrodes and the conventional dielectric material 8. The thus achieved small capacitance of the transmission line 4 leads to smaller losses and faster signal transmission due to reduced RC- and LC-time constants.

In a further embodiment, shown in FIG. 10, a large capacitor is formed is formed by a dielectric layer of HfO₂ separating a one-atom thick layer Rb film from a Si electrode 6. In this Si—HfO₂—Rb structure or, alternatively, Rb—HfO₂—Rb structure, the Rb is grown on a HfO₂ layer of 1.2 nm thickness. This can be done by electron-beam evaporation at room temperature or by sputtering to a thickness of one monolayer of Rb. In this case, capacitors are obtained whose capacitance exceeds the one of Eq. 1 by a value as high as a factor of two.

The above described embodiments may be varied in many ways. So one electrode may comprise or consists of a mixture of a conducting material and a non-conducting or semiconducting material, e.g. Rb and SiO₂ or Bi and MgO. In this case, the density of the mobile electrons of the Bi or Rb is lowered by dilution because the insulator has no mobile electrons.

Further, one electrode may comprise or consist of a layer of a perovskite or of a vanadate which, as oxides, are inert and stable also at high temperatures.

Even further, if one electrode comprises or consists of a layer of a ferromagnet or a ferrimagnet or an antiferromagnet, devices are obtained, the capacitance of which can be altered by applied magnetic fields which alter the electron system of the magnetic film. Likewise, in an FET configuration, the conductivity of a drain-source channel can be altered with magnetic fields altering the electronic properties of a magnetic gate electrode.

1. A capacitor or a capacitor-like device with at least two electrodes,
wherein
at least one electrode consists of or comprises a material or is generated as electron system, the absolute value of the charging-induced change of the electronic charging energy of which exceeds 10% of the charging-induced change of the Coulomb field energy of the capacitor.

2. The capacitor or capacitor-like device of claim 1, wherein
the at least one electrode comprises or consists of a conductive material, e.g. a metal or an alloy or a mixture of a metal or an alloy with another material, whose total areal concentration of mobile electrons or holes is <10¹⁵/cm².

3. The capacitor or capacitor-like device according to claim 1, wherein
the at least one electrode is or comprises
a material with a van-Hove singularity or
a sheet of graphene.

4. The capacitor or capacitor-like device according to claim 1, wherein
the at least one electrode is or comprises a material with strong electronic correlations as defined by the Hubbard energy U, i.e., the on-site Coulomb repulsion energy of two electrons or holes, being larger than the kinetic energy of the electrons.

5. The capacitor or capacitor-like device according to claim 1, wherein
the electron system is formed at an interface between insulators, at least one of said insulators being at least one of the group of a chalcogenide, a transition metal oxide, a nitride, and an oxinitride.

6. The capacitor or capacitor-like device according to claim 4, wherein
the insulating layer has a dielectric constant εᵣ>10.

7. The capacitor or capacitor-like device according to claim 4, wherein
the insulating layer is ferroelectric or piezoelectric.

8. The capacitor or capacitor-like device according to claim 1, wherein
the at least one electrode comprises or consists of a layer of a metal of any of the groups I or II of the periodic table, or an alloy containing at least 50 atom % of group I or II elements.

9. The capacitor or capacitor-like device according to claim 1, wherein
the at least one electrode comprises or consists of a mixture of a conducting material and a non-conducting or semiconducting material.

10. The capacitor or capacitor-like device according to claim 1, wherein
the at least one electrode comprises or consists of a layer of a perovskite or of a vanadate.

11. The capacitor or capacitor-like device according to claim 1, wherein
the at least one electrode comprises or consists of a layer of a ferromagnet or a ferrimagnet or an antiferromagnet.

12. Use of a capacitor or a capacitor-like device according to claim 1 in a field effect device or field effect transistor, especially in a gate stack of said field effect device or field effect transistor.

13. A field effect device or field effect transistor comprising a capacitor or capacitor-like device according to claim 1.

14. A memory device comprising a capacitor or capacitor-like device according to claim 1.

15. A transmission line in an electronic device forming or comprising a capacitor or capacitor-like device according to claim 1.
